(19) United States
(12) Patent Application Publication
(10) Pub. No.: US 2023/0266580 A1
(43) Pub. Date: Aug. 24, 2023

(54) PIEZOELECTRIC DRIVING ELEMENT

(71) Applicant: Panasonic Intellectual Property Management Co., Ltd., Osaka (JP)

(72) Inventor: Kensuke MIHARA, Osaka (JP)

(21) Appl. No.: 18/141,173

(22) Filed: Apr. 28, 2023

Related U.S. Application Data
(63) Continuation of application No. PCT/JP2021/040313, filed on Nov. 1, 2021.

(30) Foreign Application Priority Data
Nov. 13, 2020 (JP) 2020-189218

(51) Int. Cl. G02B 26/08; G02B 26/10

(52) U.S. Cl. CPC G02B 26/0858; G02B 26/105

(57) ABSTRACT

A piezoelectric driving element includes: a support; a plate-shaped movable part on which a rib is disposed; a pair of meander-type piezoelectric actuators each supported at one end thereof by the support; and a coupling part coupling another end of each of the pair of piezoelectric actuators and the movable part and having higher rigidity than the movable part.

### CROSS REFERENCE TO RELATED APPLICATION

This application is a continuation of International Application No. PCT/JP2021/040313 filed on Nov. 1, 2021, entitled “PIEZOELECTRIC DRIVING ELEMENT”, which claims priority under 35 U.S.C. Section 119 of Japanese Patent Application No. 2020-189218 filed on Nov. 13, 2020, entitled “PIEZOELECTRIC DRIVING ELEMENT”. The disclosures of the above applications are incorporated herein by reference.

### BACKGROUND OF THE INVENTION

### Field of the Invention

The present invention relates to a piezoelectric driving element that drives a movable part by a piezoelectric actuator and that is suitable for use, for example, for the case of performing scanning with light by a mirror disposed on the movable part.

### Description of Related Art

Recently, by using micro electro mechanical system (MEMS) technology, piezoelectric driving elements that rotate a movable part have been developed. In this type of piezoelectric driving element, a mirror is disposed on the movable part, thereby allowing scanning to be performed at a predetermined deflection angle with light incident on the mirror.

For example, Japanese Laid-Open Patent Publication No. 2008-40240 describes a light deflector including a piezoelectric actuator having a meander structure. The piezoelectric actuator includes a plurality of piezoelectric cantilevers each having a support and a piezoelectric body formed on the support. The plurality of piezoelectric cantilevers are mechanically connected at end portions thereof such that bending deformations of the respective piezoelectric cantilevers are accumulated, and each piezoelectric cantilever is bent and deformed independently when a driving voltage is applied thereto.

Also, “Jocelyn T. Nee and three others, ‘Lightweight, Optically Flat Micromirrors for Fast Beam Steering’, 2000 IEEE/LEOS International Conference on Optical MEMS (Cat. No. 00EX399), August 2000, p. 9-10” describes a structure of reinforcing the outer periphery of a movable part, on which a mirror is formed, by a rib in order to suppress bending of the mirror in this type of light deflector.

When the outer periphery of the movable part is reinforced by the rib as described above, warpage of the movable part is suppressed, but the mass of the rib becomes a load, and the resonance frequency of an element part including the movable part decreases. Such a decrease in the resonance frequency leads to a decrease in driving characteristics such as a decrease in vibration resistance and a decrease in controllability of the movable part.

### SUMMARY OF THE INVENTION

A first aspect of the present invention is directed to a piezoelectric driving element. The piezoelectric driving element according to this aspect includes: a support; a plate-shaped movable part on which a rib is disposed; a pair of meander-type piezoelectric actuators each supported at one end thereof by the support; and a coupling part coupling another end of each of the pair of piezoelectric actuators and the movable part and having higher rigidity than the movable part.

In the piezoelectric driving element according to this aspect, warpage of the plate-shaped movable part is suppressed by the rib. In addition, since the rigidity of the coupling part is increased, the rigidity of an element part (the piezoelectric actuators, the coupling part, and the movable part) is increased. Accordingly, the resonance frequency of the element part can be increased. Therefore, warpage of the movable part can be suppressed while a decrease in the driving characteristics of the movable part is suppressed.

A second aspect of the present invention is directed to a piezoelectric driving element. The piezoelectric driving element according to this aspect includes: a support; a plate-shaped movable part on which a rib is disposed; a pair of meander-type piezoelectric actuators each supported at one end thereof by the support; and a coupling part coupling another end of each of the pair of piezoelectric actuators and the movable part. The coupling part is connected to the movable part so as to be substantially included in a range between a straight line connecting a connection position between the coupling part and the piezoelectric actuator and a center of the movable part, and a rotation axis of the movable part by the piezoelectric actuator.

In the piezoelectric driving element according to this aspect, warpage of the plate-shaped movable part is suppressed by the rib. In addition, since the coupling part is connected to the movable part so as to be substantially included in the range between the straight line connecting the connection position between the coupling part and the piezoelectric actuator and the center of the movable part, and the rotation axis of the movable part by the piezoelectric actuator, the moment of inertia of the coupling part with respect to the rotation axis can be reduced. Accordingly, the resonance frequency of an element part (the piezoelectric actuators, the coupling part, and the movable part) can be increased. Therefore, warpage of the movable part can be suppressed while a decrease in the driving characteristics of the movable part is suppressed.

The effects and the significance of the present invention will be further clarified by the description of the embodiments below. However, the embodiments below are merely examples for implementing the present invention. The present invention is not limited by the description of the embodiments below in any way.

### BRIEF DESCRIPTION OF THE DRAWINGS

FIG. 1 is a plan view schematically showing a configuration of a piezoelectric driving element according to Embodiment 1;

FIG. 2 is a plan view schematically showing the configuration of the piezoelectric driving element according to Embodiment 1;

FIG. 3A is a diagram schematically showing a configuration of a C11-C12 cross-section obtained by cutting a vibration part according to Embodiment 1 along a plane parallel to an X-Z plane, as viewed in a Y-axis positive direction;

FIG. 3B is a diagram schematically showing a configuration of a C21-C22 cross-section obtained by cutting a vibration part according to Embodiment 1 along a plane parallel to a Y-Z plane, as viewed in an X-axis negative direction;

FIG. 3C is a diagram schematically showing a configuration of a C31-C32 cross-section by cutting a movable part, a rib, a mirror, and coupling parts according to Embodiment 1 along a plane passing through the center of the movable part and parallel to the Y-Z plane, as viewed in the X-axis negative direction;

FIG. 4 is a plan view schematically showing a configuration of a piezoelectric driving element according to Embodiment 2;

FIG. 5A is a plan view schematically showing a configuration of a piezoelectric driving element according to a comparative example;

FIG. 5B is a diagram schematically showing a configuration of a C41-C42 cross-section by cutting a vibration part according to the comparative example along a plane parallel to the Y-Z plane, as viewed in the X-axis negative direction;

FIG. 5C is a diagram schematically showing a configuration of a C51-052 cross-section by cutting a movable part, a rib, a mirror, and coupling parts according to the comparative example along a plane passing through the center of the movable part and parallel to the Y-Z plane, as viewed in the X-axis negative direction;

FIG. 6A is a plan view schematically showing a configuration of a piezoelectric driving element according to Model 1 corresponding to Embodiment 1;

FIG. 6B is a diagram schematically showing a configuration of a C61-C62 cross-section by cutting a movable part, ribs, a mirror, and coupling parts according to Model 1 corresponding to Embodiment 1 along a plane passing through the center of the movable part and parallel to the Y-Z plane, as viewed in the X-axis negative direction;

FIG. 6C is a plan view schematically showing a configuration of a piezoelectric driving element according to Model 2 corresponding to Embodiment 2;

FIG. 7 is a table showing the results of simulation for the comparative example and Models 1 and 2;

FIG. 8A and FIG. 8B are each a plan view schematically showing a configuration of a piezoelectric driving element according to a modification of the coupling parts;

FIG. 9A and FIG. 9B are each a plan view schematically showing a configuration of a piezoelectric driving element according to a modification of the rib;

FIG. 10A is a diagram schematically showing a configuration of a C31-C32 cross-section by cutting a movable part, a rib, a mirror, and coupling parts according to a modification of connection between the rib and each coupling part along a plane passing through the center of the movable part and parallel to the Y-Z plane, as viewed in the X-axis negative direction;

FIG. 10B is a diagram schematically showing a configuration of a C31-C32 cross-section by cutting a movable part, a rib, a mirror, coupling parts, and metal materials according to a modification where each coupling part is covered with a metal material, along a plane passing through the center of the movable part and parallel to the Y-Z plane, as viewed in the X-axis negative direction;

FIG. 11 is a plan view schematically showing a configuration of a piezoelectric driving element according to a modification; and

FIG. 12 is a table showing the results of simulation for the comparative example and Model 3.

It should be noted that the drawings are solely for description and do not limit the scope of the present invention by any degree.

### DETAILED DESCRIPTION

In the following embodiments, each piezoelectric driving element is an element for rotating a mirror around a rotation axis R10 and scanning a target region using light incident on the mirror. This type of piezoelectric driving element is sometimes also referred to as light deflector or mirror actuator. The piezoelectric driving element is not limited to one for rotating the mirror, but may rotate a member or a film other than the mirror. The following embodiments are each one embodiment of the present invention, and the present invention is not limited to the following embodiments in any way.

Hereinafter, embodiments of the present invention will be described with reference to the drawings. For convenience, in each drawing, X, Y, and Z axes that are orthogonal to each other are additionally shown, and the Z-axis positive direction is the vertical upward direction.

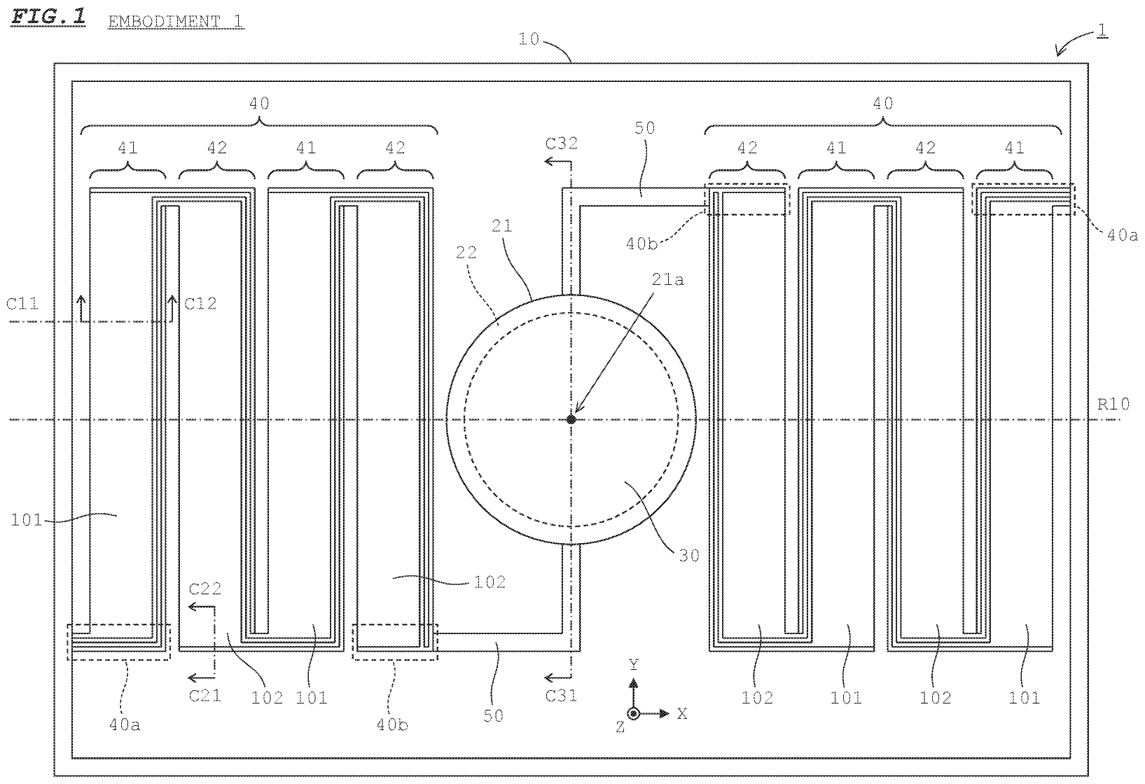

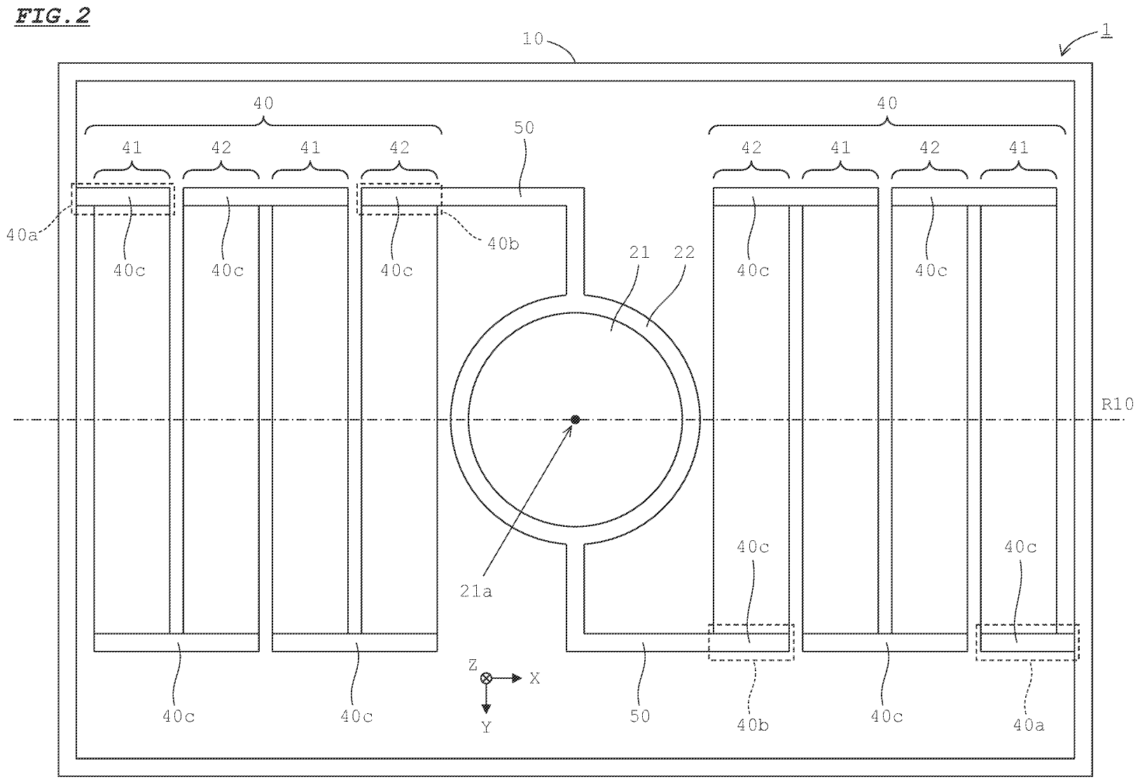

FIG. 1 and FIG. 2 are each a plan view schematically showing a configuration of a piezoelectric driving element 1. FIG. 1 and FIG. 2 are plan views of the piezoelectric driving element 1 as viewed in the Z-axis negative direction and the Z-axis positive direction, respectively.

Referring to FIG. 1 and FIG. 2, the piezoelectric driving element 1 includes a support 10, a movable part 21, a rib 22, a mirror 30, a pair of piezoelectric actuators 40, and a pair of coupling parts 50.

The support 10 is a frame-shaped member provided with an opening at the center thereof. The movable part 21 has a plate shape and a circular shape. The rib 22 has a ring shape and is disposed near the outer periphery of a surface on the Z-axis negative side of the movable part 21. When viewed in the Z-axis direction, the outer shape of the rib 22 matches the outer shape of the movable part 21. The mirror 30 has a circular shape and is disposed on a surface on the Z-axis positive side of the movable part 21. When viewed in the Z-axis direction, the shape of the mirror 30 matches the shape of the movable part 21. The Z-axis positive side of the mirror 30 is a mirror surface, and light incident on the mirror surface from the Z-axis positive side is reflected by the mirror surface.

The two piezoelectric actuators 40 are disposed on the X-axis positive side and the X-axis negative side of the movable part 21, respectively, and are disposed and configured so as to be point-symmetrical with respect to a center 21a of the movable part 21 in a plan view. Outer end portions 40a in the X-axis direction of the two piezoelectric actuators 40 are supported by the support 10.

The two coupling parts 50 are connected to the movable part 21 at positions symmetrical with respect to the center 21a of the movable part 21. The two coupling parts 50 are disposed on the Y-axis positive side and the Y-axis negative side of the movable part 21, respectively, and are disposed and configured so as to be point-symmetrical with respect to the center 21a of the movable part 21 in a plan view. Each coupling part 50 has a beam-like shape. The coupling part 50 couples an inner end portion 40b in the X-axis direction of the piezoelectric actuator 40 to the movable part 21. The two coupling parts 50 each have an L-shape in a plan view.

Each piezoelectric actuator 40 is a so-called meander-type actuator. That is, each piezoelectric actuator 40 includes two vibration parts 41 and two vibration parts 42 which are alternately coupled to each other so as to form a meander shape. The vibration parts 41 and 42 each have a rectangular shape in a plan view, and are coupled at end portions in the Y-axis direction to the vibration parts adjacent thereto. In the piezoelectric actuator 40, the odd-numbered vibration parts from the outside are the vibration parts 41, and the even-numbered vibration parts from the outside are the vibration parts 42.

In the piezoelectric actuator 40 on the X-axis positive side, an end portion on the Y-axis positive side of the outermost vibration part 41 is the end portion 40a connected to the support 10, and an end portion on the Y-axis positive side of the innermost vibration part 42 is the end portion 40b connected to the coupling part 50. In the piezoelectric actuator 40 on the X-axis negative side, an end portion on the Y-axis negative side of the outermost vibration part 41 is the end portion 40a connected to the support 10, and an end portion on the Y-axis negative side of the innermost vibration part 42 is the end portion 40b connected to the coupling part 50. Reinforcing portions 40c (see FIG. 2) are disposed on the Z-axis negative side near where each vibration part 41 and each vibration part 42 are connected and on the Z-axis negative side of each end portion 40a or 40b.

The vibration parts 41 and 42 have upper electrodes 101 and 102 on the upper surface (Z-axis positive side surface) side. The upper electrodes 101 and 102 are each disposed on the upper surface side of the vibration parts 41 and 42 along the meander shape of the piezoelectric actuator 40 from the end portion 40a to the end portion 40b. The upper electrode 101 is disposed on the upper surface side of each vibration part 41 so as to have an area substantially equal to that of the vibration part 41, and is disposed on the upper surface side of each vibration part 42 so as to extend in a linear manner along the edge of the vibration part 42. Meanwhile, the upper electrode 102 is disposed on the upper surface side of each vibration part 42 so as to have an area substantially equal to that of the vibration part 42, and is disposed on the upper surface side of each vibration part 41 so as to extend in a linear manner along the edge of the vibration part 41. The upper electrodes 101 and 102 extend to the outside of the end portion 40a and are connected to a drive part which is for applying a voltage and is not shown.

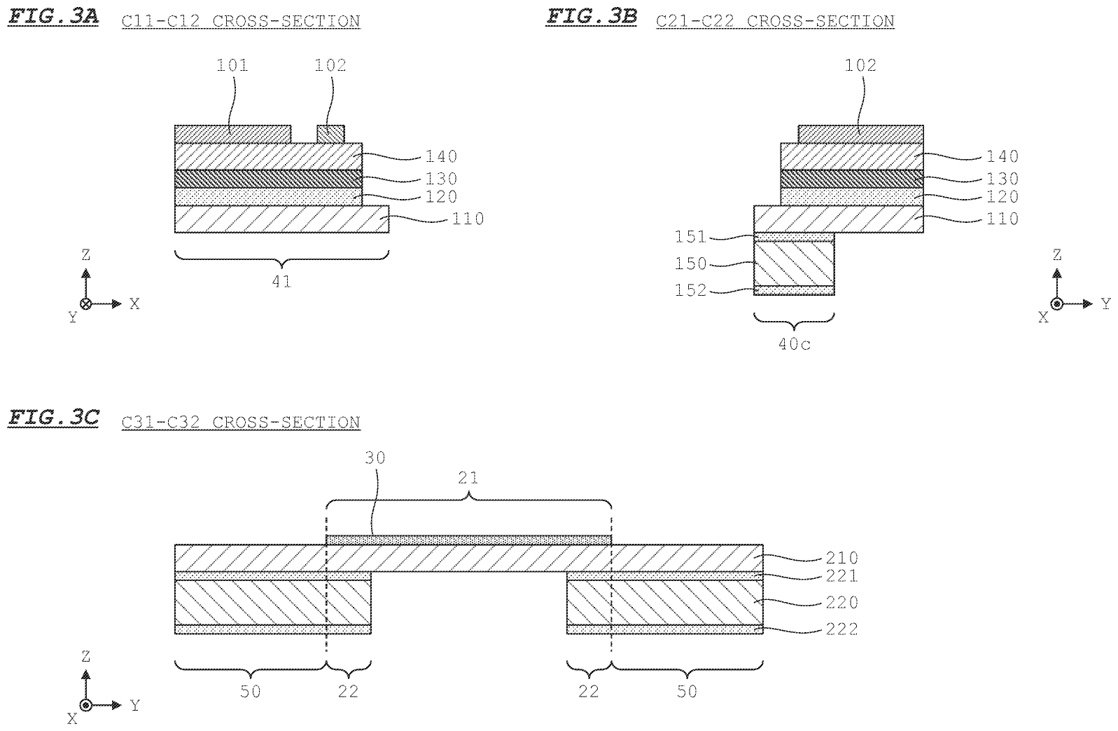

FIG. 3A is a diagram schematically showing a configuration of a C11-C12 cross-section obtained by cutting a vibration part 41 of the piezoelectric actuator 40 on the X-axis negative side in FIG. 1 along a plane parallel to the X-Z plane, as viewed in the Y-axis positive direction.

The configuration shown FIG. 3A is the same for the other vibration part 41 of the piezoelectric actuator 40 on the X-axis negative side. In addition, a configuration of a cross-section of each vibration part 42 of the piezoelectric actuator 40 on the X-axis negative side is a configuration in which, in FIG. 3A, the upper electrode 101 is replaced with the upper electrode 102, and the upper electrode 102 is replaced with the upper electrode 101. In addition, a configuration of a cross-section of the piezoelectric actuator 40 on the X-axis positive side is a configuration obtained by inverting the configuration of FIG. 3A in the X-axis direction.

Each vibration part 41 includes a device layer 110, a thermal oxide film 120, a lower electrode 130, a piezoelectric body 140, and the upper electrodes 101 and 102. The device layer 110 is composed of a Si substrate, and the thermal oxide film 120 is composed of SiO₂. The lower electrode 130 is composed of a metal electrode film. The piezoelectric body 140 is composed of, for example, lead zirconate titanate (PZT). The upper electrodes 101 and 102 are disposed on the upper surface of the piezoelectric body 140. In the X-axis direction, the width of the device layer 110 is slightly longer than those of the thermal oxide film 120, the lower electrode 130, and the piezoelectric body 140. Since FIG. 3A is a diagram showing the vibration part 41, the upper electrode 101 is longer than the upper electrode 102 in the X-axis direction, but in the case of each vibration part 42, the upper electrode 102 is longer than the upper electrode 101 in the X-axis direction.

FIG. 3B is a diagram schematically showing a configuration of a C21-C22 cross-section obtained by cutting a portion around the end on the Y-axis negative side of a vibration part 42 of the piezoelectric actuator 40 on the X-axis negative side of FIG. 1 along a plane parallel to the Y-Z plane, as viewed in the X-axis negative direction.

The configuration shown in FIG. 3B is the same for a portion around the end on the Y-axis negative side of the other vibration part 42 of the piezoelectric actuator 40 on the X-axis negative side. In addition, a configuration of a portion around the end on the Y-axis positive side of each vibration part 41 of the piezoelectric actuator 40 on the X-axis negative side is a configuration obtained by inverting the configuration of FIG. 3B in the Y-axis direction. Moreover, a configuration of a portion around the end on the Y-axis negative side of each vibration part 41 and a configuration of a portion around the end on the Y-axis positive side of each vibration part 42 of the piezoelectric actuator 40 on the X-axis negative side are the same as the configuration of FIG. 3B, except that the upper electrodes 101 and 102 are aligned in the Y-axis direction around the end portions as shown in FIG. 1. Moreover, a configuration of a cross-section of the piezoelectric actuator 40 on the X-axis positive side is a configuration obtained by inverting the configuration of FIG. 3B in the X-axis direction.

As shown in FIG. 3B, at the end portion of the vibration part 41 connected to the adjacent vibration part 42, in addition to the configuration of FIG. 3A, the reinforcing portion 40c is disposed on the Z-axis negative side of the device layer 110. The reinforcing portion 40c includes a base layer 150 and thermal oxide films 151 and 152. The base layer 150 is composed of a Si substrate, and the thermal oxide films 151 and 152 are composed of SiO₂. The device layer 110 protrudes in the Y-axis direction from the thermal oxide film 120, the lower electrode 130, and the piezoelectric body 140, and the reinforcing portion 40c is disposed at an end portion in the Y-axis direction of the device layer 110. The reinforcing portion 40c extends in a straight manner in the X-axis direction to an end portion of the adjacent vibration part 42.

In the piezoelectric actuator 40, the device layer 110 has the same shape as the outer shape of the piezoelectric actuator 40 shown in FIGS. 1 and 2, and each part of the piezoelectric actuator 40 is disposed as shown in FIGS. 3A and 3B through a semiconductor film formation process with the device layer 110 as a base. Accordingly, as shown in FIG. 1, the vibration parts 41 and 42 are formed in the piezoelectric actuator 40.

FIG. 3C is a diagram schematically showing a configuration of a C31-C32 cross-section obtained by cutting the movable part 21, the rib 22, the mirror 30, and the coupling parts 50 along a plane passing through the center 21a of the movable part 21 and parallel to the Y-Z plane in FIG. 1, as viewed in the X-axis negative direction.

The movable part 21 includes a device layer 210. The device layer 210 is composed of a Si substrate. The mirror 30 is an optical reflection film formed on the upper surface of the device layer 210. The mirror 30 is composed of, for example, a dielectric multilayer film, a metal film, or the like. The rib 22 includes a base layer 220 and thermal oxide films 221 and 222. The base layer 220 is composed of a Si substrate, and the thermal oxide films 221 and 222 are composed of SiO₂. Each coupling part 50 includes the device layer 210, the base layer 220, and the thermal oxide films 221 and 222. In Embodiment 1, in a direction parallel to the X-Y plane, the device layer 210 extends over the regions of the movable part 21 and the coupling part 50, and the base layer 220 and the thermal oxide films 221 and 222 extend over the regions of the rib 22 and the coupling parts 50.

The movable part 21, the rib 22, and the coupling parts 50 are formed by processing a SOI substrate composed of a Si substrate and SiO₂ formed on the surface of the Si substrate. First, a SOI substrate including the device layer 210 and the thermal oxide film 221 and a SOI substrate including the base layer 220 and the thermal oxide film 222 are attached together. A region corresponding to the rib 22 and the coupling parts 50 is subjected to masking treatment, and a region corresponding to the hole at the center of the rib 22 is removed by etching. Thereafter, a masking member is removed, and the mirror 30 is formed on the upper surface of the movable part 21.

The device layer 110 included in each piezoelectric actuator 40 and the device layer 210 in the components (the movable part 21, the rib 22, and the coupling parts 50) other than the piezoelectric actuator 40 are integrally formed using a common Si substrate.

Also, in addition to the movable part 21, the rib 22, and the coupling parts 50, the entirety of the piezoelectric driving element 1 is formed by processing a SOI substrate. That is, each part of the piezoelectric driving element 1 is collectively formed by performing masking and etching on a SOI substrate.

Here, warpage and bending of the movable part 21 are usually likely to be caused by thermal stress generated during the formation of the mirror 30. On the other hand, in Embodiment 1, since the rib 22 is formed in advance on the back surface side of the movable part 21, warpage and bending of the movable part 21 can be suppressed during the formation of the mirror 30. In addition, each coupling part 50 is thicker than the movable part 21, and thus has higher rigidity than the movable part 21. That is, each coupling part 50 is configured to be less likely to bend. Accordingly, it is easier for vibrations caused by the piezoelectric actuators 40 to be transmitted to the movable part 21.

Next, the drive of the piezoelectric driving element 1 configured as shown in FIG. 1 to FIG. 3C will be described.

When driving the piezoelectric driving element 1, a voltage is applied to each of the upper electrodes 101 and 102 such that the movable part 21 and the mirror 30 repeatedly rotationally vibrate around the rotation axis R10 (see FIGS. 1 and 2). When the voltage is applied to each of the upper electrodes 101 and 102, the voltage is applied to the piezoelectric body 140 (see FIGS. 3A and 3B) located directly below the upper electrodes 101 and 102, and the vibration parts 41 and 42 are deformed so as to be curved in the Z-axis positive direction or the Z-axis negative direction due to the inverse piezoelectric effect of the piezoelectric body 140.

Specifically, voltages having the same phase are applied to the upper electrode 101 of the piezoelectric actuator 40 on the X-axis positive side and the upper electrode 102 of the piezoelectric actuator 40 on the X-axis negative side, and voltages having opposite phases are applied to the upper electrode 102 of the piezoelectric actuator 40 on the X-axis positive side and the upper electrode 101 of the piezoelectric actuator 40 on the X-axis negative side. By making the phases of the voltages applied to the upper electrodes 101 and 102 to be opposite phases as described above, the adjacent two vibration parts 41 and 42 are displaced in opposite directions. Accordingly, these displacements are accumulated around the rotation axis R10, causing the movable part 21 and the mirror 30 to repetitively rotationally vibrate.

### Effects of Embodiment 1

According to Embodiment 1, the following effects are achieved.

The rib 22 is disposed on the plate-shaped movable part 21. In addition, the coupling parts 50 having higher rigidity than the movable part 21 couple the end portions 40b of the piezoelectric actuators 40 to the movable part 21. According to this configuration, warpage of the plate-shaped movable part 21 is suppressed by the rib 22. In addition, since the rigidity of the coupling parts 50 is increased, the rigidity of an element part (the piezoelectric actuators 40, the coupling parts 50, and the movable part 21) is increased. Accordingly, the resonance frequency of the element part can be increased, so that a decrease in the driving characteristics of the mirror 30 can be suppressed.

In Embodiment 1, the reinforcing portions 40c are disposed at the end portions in the Y-axis direction of the vibration parts 41 and 42. When the reinforcing portions 40c are provided as described above, the rigidity of the element part (the piezoelectric actuators 40, the coupling parts 50, and the movable part 21) is increased. Accordingly, in addition to the effect by the coupling parts 50, the resonance frequency of the element part can be further increased.

Each coupling part 50 is thicker than the movable part 21. Thus, the rigidity of the coupling part 50 can be easily increased by adjusting the thickness of the coupling part 50.

The end portion of each coupling part 50 extends to the rib 22 and is connected to the rib 22. That is, each coupling part 50 is directly connected to the rib 22. Accordingly, the pair of piezoelectric actuators 40 are coupled to each other by a highly-rigid structure (the coupling parts 50 and the rib 22), and thus the rigidity of the element part (the piezoelectric actuators 40, the coupling parts 50, and the movable part 21) is increased, so that the resonance frequency of the element part can be increased. Therefore, a decrease in the driving characteristics of the movable part 21 can be further suppressed.

As shown in FIG. 3C, the rib 22 and the coupling parts 50 are composed of the same material (Si substrate), and each coupling part 50 has a thickness equal to the sum of the thicknesses of the movable part 21 and the rib 22. Accordingly, the rib 22 and the coupling parts 50 can be molded at the same time, so that the manufacturing of the piezoelectric driving element 1 is facilitated.

The coupling parts 50 are connected to the movable part 21 at the positions symmetrical with respect to the center 21a of the movable part 21. According to this configuration, the movable part 21 can be supported in a well-balanced manner by the coupling parts 50, so that the movable part 21 can be stably driven.

The mirror 30 is disposed on the movable part 21. Accordingly, the mirror 30 can be driven at a high resonance frequency while warpage of the mirror 30 is suppressed. Therefore, the quality of light (e.g., laser beam) reflected by the mirror 30 can be improved, and scanning can be performed with this light at a high speed.

### Embodiment 2

In Embodiment 2, the method for connecting each coupling part 50 to the movable part 21 is changed from Embodiment 1 described above. The configuration other than the connection method for each coupling part 50 is the same as in Embodiment 1 described above.

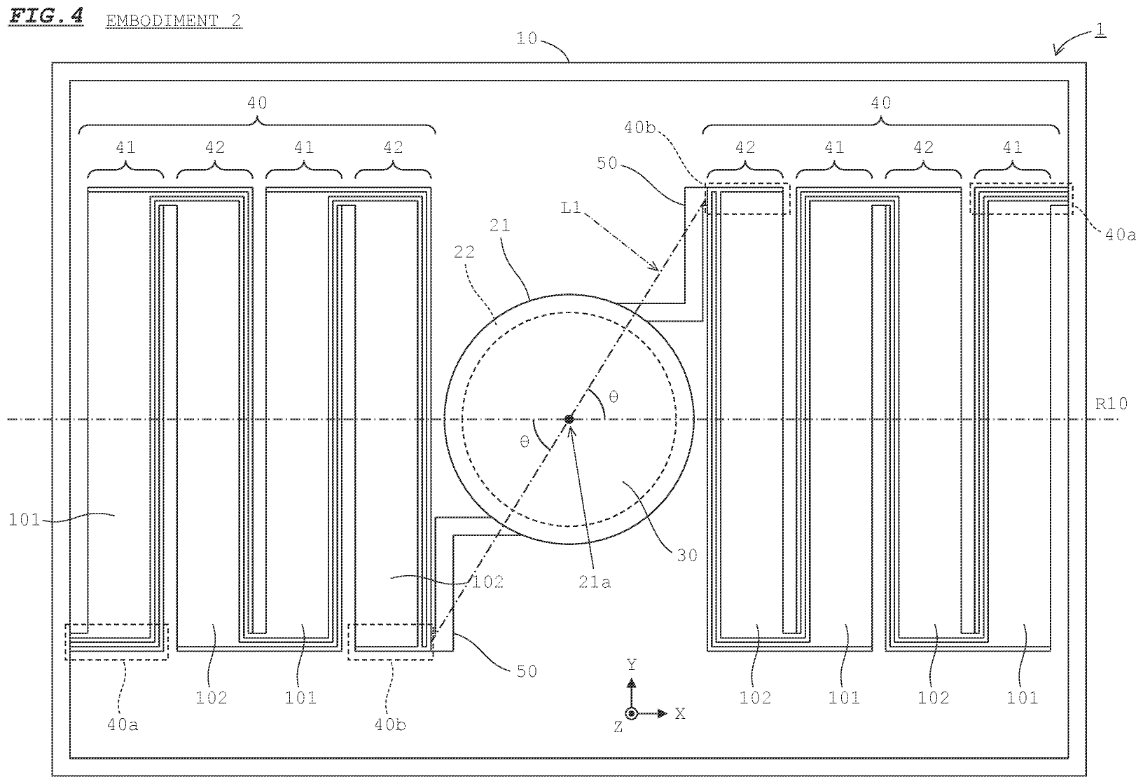

FIG. 4 is a plan view schematically showing the configuration of the piezoelectric driving element 1.

A straight line L1 is a straight line connecting the connection position between each coupling part 50 and the piezoelectric actuator 40 (end portion 40b) and the center 21a of the movable part 21. Each coupling part 50 is connected to the movable part 21 so as to be substantially included in a range (range of an angle θ) between the straight line L1 and the rotation axis R10 of the movable part 21 by the piezoelectric actuator 40. When each coupling part 50 is disposed so as to be substantially included in the range of the angle θ as described above, the moment of inertia of the coupling part 50 with respect to the rotation axis R10 can be reduced.

<Simulation for Driving Characteristics>

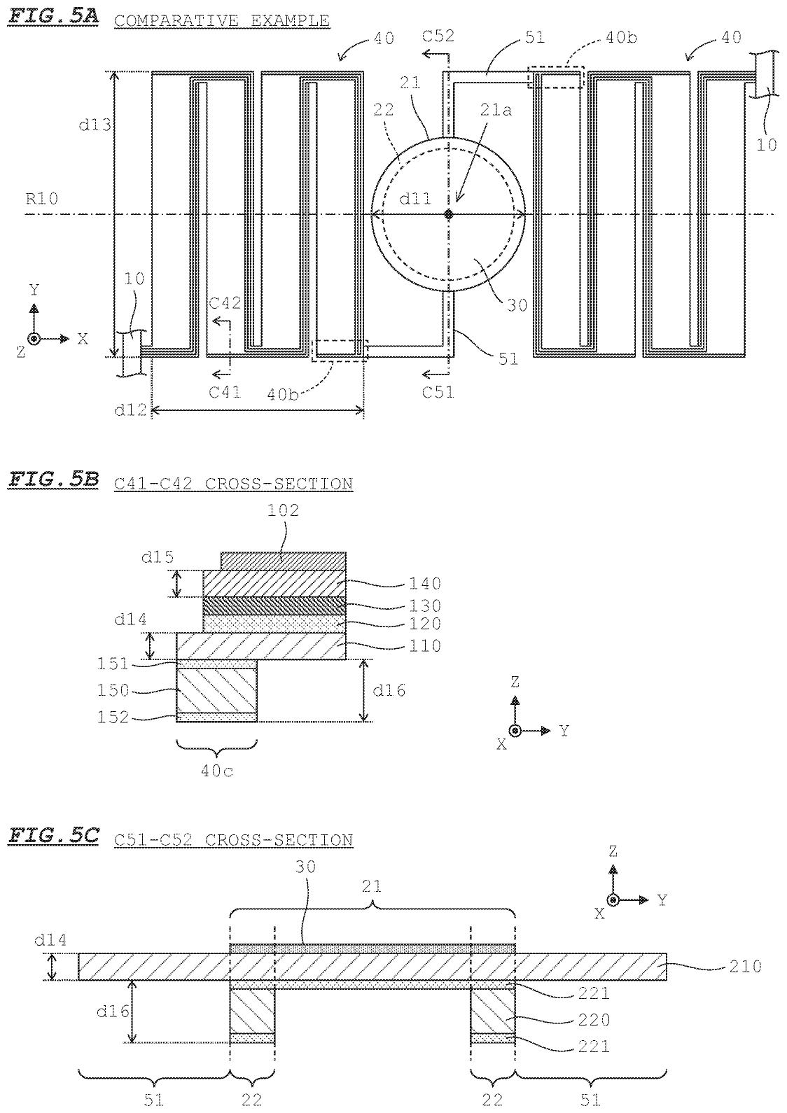

The inventor performed simulation by a finite element method, for the driving characteristics of Model 1 corresponding to the configuration of Embodiment 1, Model 2 corresponding to the configuration of Embodiment 2, and a comparative example different from Embodiments 1 and 2. In this simulation, the configuration of each piezoelectric driving element 1 is the substantially the same as that shown in FIG. 1 or 4. Hereinafter, in this simulation, components, sizes of each part, etc., different from those in FIGS. 1 and 4 will be described. Among the components of Models 1 and 2, the same components as those of the comparative example will be described with reference to the configuration of the comparative example shown in FIGS. 5A to 5C.

FIG. 5A is a plan view schematically showing the configuration of the comparative example.

In this simulation, in each of the comparative example and Models 1 and 2, a diameter d11 of the movable part 21 was set to 1.5 mm. A width d12 in the X-axis direction of each piezoelectric actuator 40 was set to 2.3 mm, and a width d13 in the Y-axis direction of each piezoelectric actuator 40 was set to 1.8 mm.

In the comparative example, as shown in FIG. 5A, coupling parts 51 were disposed instead of the coupling parts 50, as compared to the configuration of Embodiment 1 shown in FIG. 1. The shape of each coupling part 51 in a plan view is the same as that of each coupling part 50 of Embodiment 1, but the thickness of each coupling part 51 is smaller than that of each coupling part 50 of Embodiment 1.

FIG. 5B is a diagram schematically showing a configuration of a C41-C42 cross-section obtained by cutting the piezoelectric actuator 40 along a plane parallel to the Y-Z plane in the configuration of the comparative example of FIG. 5A, as viewed in the X-axis negative direction.

In this simulation, in each of the comparative example and Models 1 and 2, a thickness d14 of the device layer 110 was set to 10 μm, a thickness d15 of the piezoelectric body 140 was set to 3 μm, and a thickness d16 of the base layer 150 and the thermal oxide films 151 and 152 was set to 270 μm.

FIG. 5C is a diagram schematically showing a configuration of a C51-052 cross-section obtained by cutting the movable part 21, the rib 22, the mirror 30, and the coupling parts 51 along a plane passing through the center 21a of the movable part 21 and parallel to the Y-Z plane in FIG. 5A, as viewed in the X-axis negative direction.

In this simulation, in each of the comparative example and Models 1 and 2, the thickness of the device layer 210 was set to 10 μm which is equal to the thickness d14 in FIG. 5B, and the thickness of the base layer 220 and the thermal oxide films 221 and 222 was set to 270 μm which is equal to the thickness d16 in FIG. 5B.

In the comparative example, as shown in FIG. 5C, each coupling part 51 was composed of only the device layer 210 as in the movable part 21. Each coupling part 51 of the comparative example has a thickness equal to that of the movable part 21, and thus the rigidity of each coupling part 51 is lower than that of each coupling part 50 of Models 1 and 2. In the comparative example, the rigidity of each coupling part 51 in the Z-axis direction is equal to the rigidity of the movable part 21 itself on which no rib 22 is disposed.

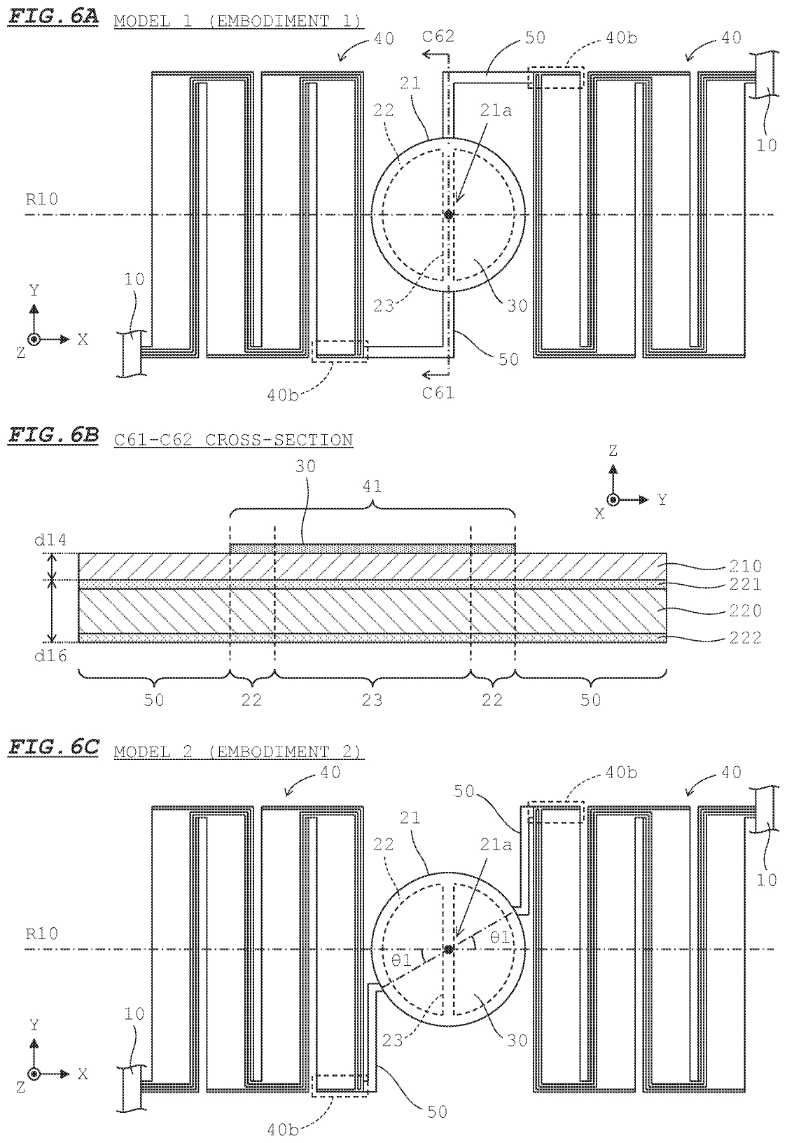

FIG. 6A is a plan view schematically showing a configuration of Model 1 corresponding to Embodiment 1.

As described above, the configuration of Model 1 is the same as that of the comparative example in a plan view. However, in Model 1, as in Embodiment 1, the movable part 21 and the rib 22 are connected to the piezoelectric actuators 40 by the coupling parts 50 different from those of the comparative example. In addition, in each of Models 1 and 2, in addition to the rib 22 shown in FIG. 1, a rib 23 is disposed on the surface on the Z-axis negative side of the movable part 21 so as to extend in a straight manner in the Y-axis direction.

FIG. 6B is a diagram schematically showing a C61-C62 cross-section obtained by cutting the movable part 21, the ribs 22 and 23, the mirror 30, and the coupling parts 50 along a plane passing through the center 21a of the movable part 21 and parallel to the Y-Z plane in the configuration of Model 1 in FIG. 6A, as viewed in the X-axis negative direction.

As described above, in the configuration of Model 1, the thickness of the device layer 210 is equal to the thickness d14 (10 μm) of the comparative example shown in FIG. 5C, and the thickness of the base layer 220 and the thermal oxide films 221 and 222 is equal to the thickness d16 (270 μm) of the comparative example shown in FIG. 5C. However, in Model 1, each coupling part 50 is composed of the device layer 210, the base layer 220, and the thermal oxide films 221 and 222.

FIG. 6C is a plan view schematically showing a configuration of Model 2 corresponding to Embodiment 2.

In Model 2, the position at which each coupling part 50 is connected to the movable part 21 and the rib 22 was set to a position at an angle θ1 with respect to the rotation axis R10 with the center 21a of the movable part 21 as a center. Here, the angle θ1 was set to 30°. In this case as well, each coupling part 50 is substantially included in a range between the straight line L1 (see FIG. 4) and the rotation axis R10. Also, in Model 2 as well, as in Model 1, each coupling part 50 is composed of the device layer 210, the base layer 220, and the thermal oxide films 221 and 222. Each dimension of Model 2 was set so as to be the same as that of Model 1, except for the method for disposing each coupling part 50.

Under the above conditions, first, the inventor measured the warpage of the mirror 30 in a non-driven state, based on thermal stress obtained through a preliminary experiment and the conditions of this simulation. Next, the inventor drove the piezoelectric driving element 1 to rotate the movable part 21 and the mirror 30, and measured the resonance frequency of the element part (the piezoelectric actuators 40, the coupling parts, and the movable part 21) and a deflection angle thereof around the rotation axis R10 at this time.

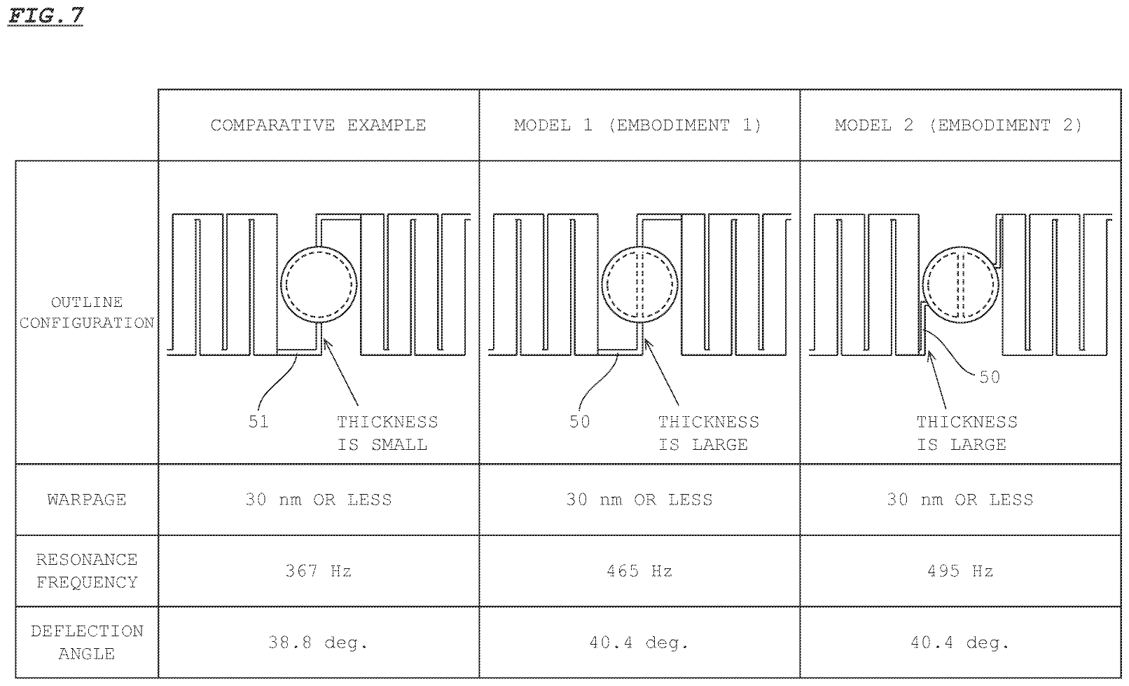

FIG. 7 is a table showing the results of this simulation.

The value of the warpage was 30 nm or less in each of the comparative example and Models 1 and 2. When the inventor measured the warpage of the mirror 30 in the case where no ribs 22 and 23 were disposed, the value of the warpage was as large as several hundreds of nanometers. In this simulation, it is confirmed that by disposing the rib 22 on the movable part 21 in the case of the comparative example and by disposing the ribs 22 and 23 on the movable part 21 in the cases of Models 1 and 2, warpage is suppressed in each of the above cases.

The value of the resonance frequency was 367 Hz in the comparative example, 465 Hz in Model 1, and 495 Hz in Model 2. In this simulation, a higher resonance frequency was obtained in Model 1 than in the comparative example, and further, a higher resonance frequency was obtained in Model 2 than in Model 1. From this, it is confirmed that by increasing the thickness of each coupling part 50 to increase the rigidity of each coupling part 50, a higher resonance frequency is obtained. Moreover, it is confirmed that by disposing each coupling part 50 and reducing the moment of inertia of each coupling part 50 as in Model 2, an even higher resonance frequency is obtained.

The value of the deflection angle was 38.8° in the comparative example, and 40.4° in Models 1 and 2. In this simulation, a larger deflection angle was obtained in Models 1 and 2 than in the comparative example. The reason why the deflection angle in the comparative example was smaller is inferred to be that the thickness of each coupling part 51 was set smaller and the rigidity of the element part (the piezoelectric actuators 40, the coupling parts 51, and the movable part 21) was lower. On the other hand, the reason why the deflection angles in Models 1 and 2 were larger is inferred to be that the thickness of each coupling part 50 was set larger and the rigidity of the element part (the piezoelectric actuators 40, the coupling parts 50, and the movable part 21) was increased, so that a rotational moment generated by each piezoelectric actuator 40 was transmitted to the movable part 21 without being impaired by the coupling part 50. Therefore, from the viewpoint of increasing the deflection angle, it can be said that it is preferable that the rigidity of each coupling part 50 is higher.

### Effects of Embodiment 2

According to Embodiment 2, the following effects are achieved.

Each coupling part 50 is connected to the movable part 21 so as to be substantially included in the range between the straight line L1 and the rotation axis R10 (rotary axis). That is, a large portion of each coupling part 50 is disposed so as to be included in the above range, so that the coupling part 50 is substantially included in the above range. According to this configuration, since each coupling part 50 is located in a range close to the rotation axis R10, the moment of inertia of the coupling part 50 with respect to the rotation axis R10 can be reduced. Therefore, the resonance frequency of the element part (the piezoelectric actuators 40, the coupling parts 50, and the movable parts 21) can be increased, so that a decrease in the driving characteristics of the mirror 30 can be further suppressed.

### Modifications

The configuration of the piezoelectric driving element 1 can be modified in various ways other than the configurations shown in the above embodiments.

For example, in Embodiments 1 and 2 described above, as shown in FIGS. 1 and 4, each coupling part 50 has an L-shape, but may have another shape.

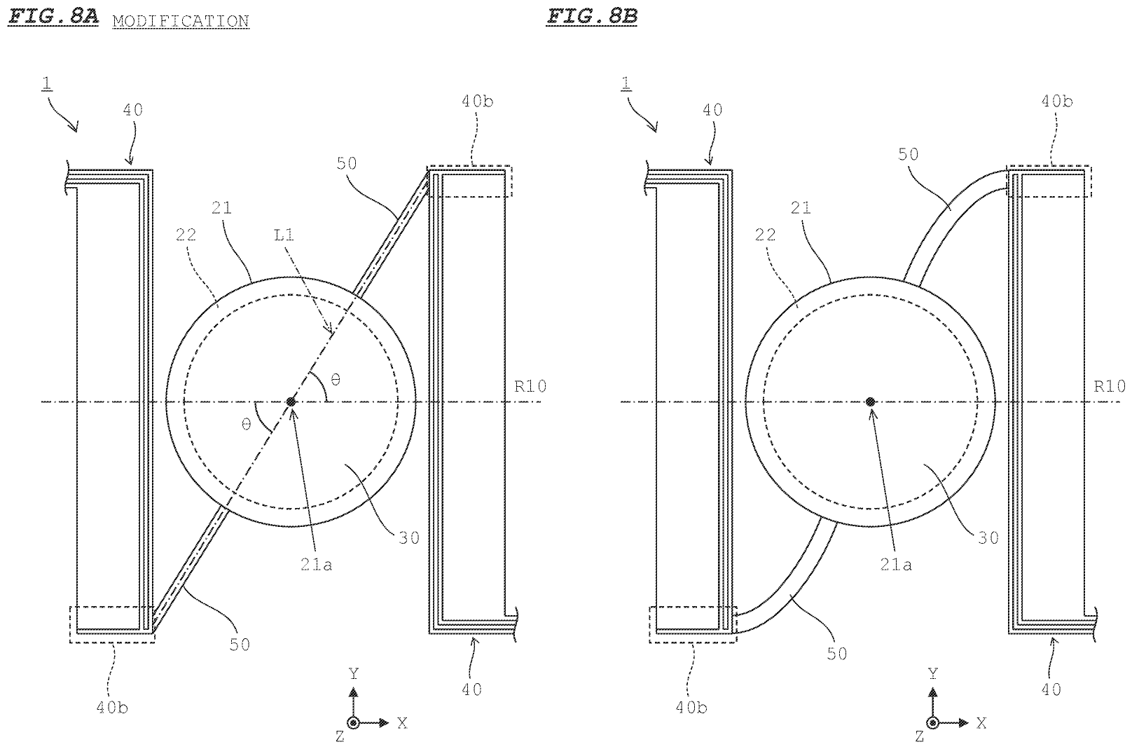

For example, as shown in FIG. 8A, each coupling part 50 may extend in a straight manner so as to have angles with respect to the X axis and the Y axis in the X-Y plane. In this case as well, each coupling part 50 is substantially included in the range between the straight line L1 and the rotation axis R10, so that the moment of inertia of the coupling part 50 is reduced. In addition, as shown in FIG. 8B, each coupling part 50 may have a curved shape.

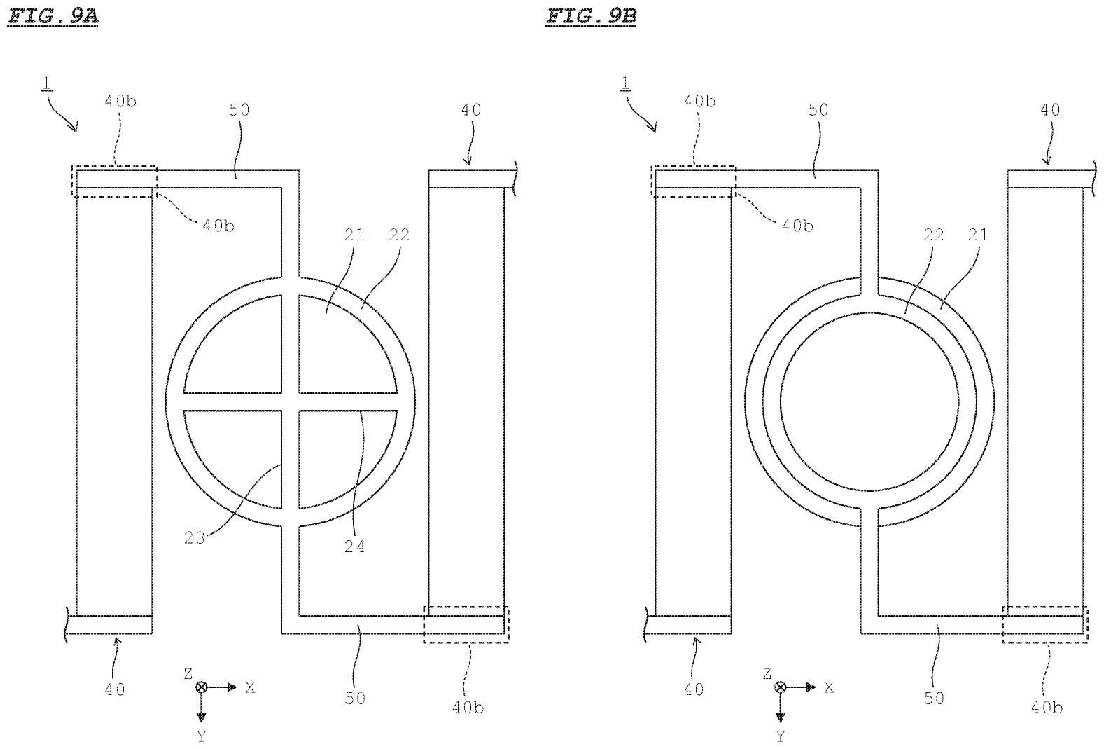

In Embodiments 1 and 2 described above, the rib 22 has a ring shape in a plan view, but the shape of the rib for suppressing the warpage of the movable part 21 is not limited to a ring shape. For example, as shown in FIGS. 6A and 6C, the rib 23 having a straight shape may be added in the radial direction of the rib 22. As shown in FIG. 9A, in addition to the ribs 22 and 23, a rib 24 having a straight shape may be further added in the radial direction of the rib 22. In this case, the rib 22 and the rib 23 are disposed, for example, so as to be orthogonal to each other. In addition, the rib 22 may have a rectangular shape in a plan view. Moreover, the rib 22 may be omitted in the configuration of FIG. 9A.

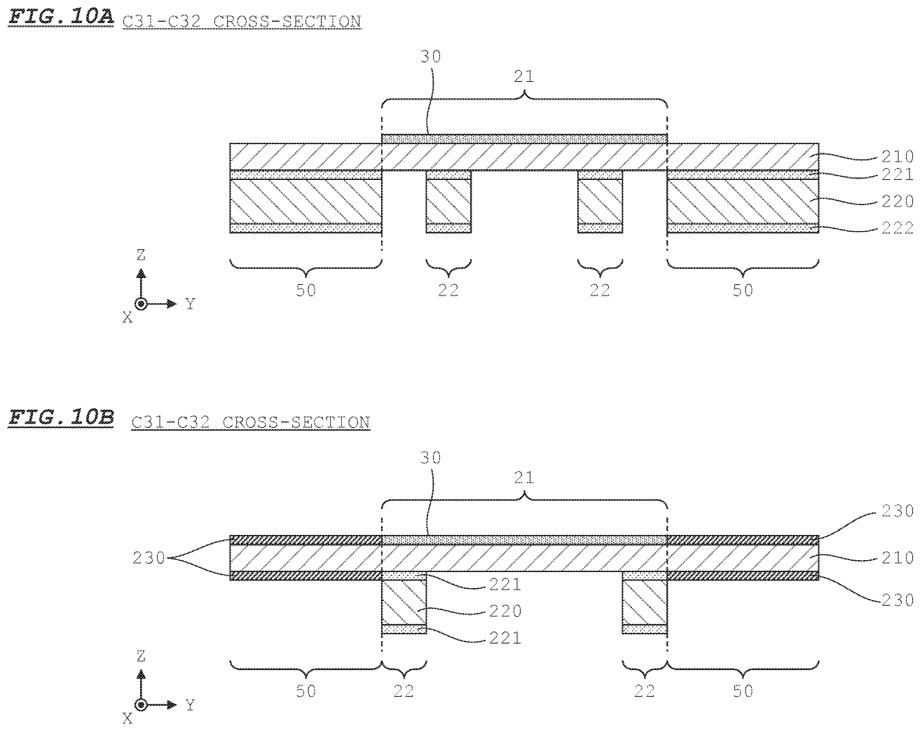

In Embodiments 1 and 2 described above, the ring-shaped rib 22 is disposed at the outer peripheral portion of the movable part 21, but is not limited thereto, and may be disposed slightly inward from the outer peripheral portion of the movable part 21 as shown in FIG. 9B. In this case as well, the rib 22 and each coupling part 50 are integrally formed from the same material. Moreover, in the case of the configuration of FIG. 9B, as shown in FIG. 10A, the rib 22 and each coupling part 50 may not necessarily be integrally formed. However, from the viewpoint of improving the resonance frequency, preferably, the rib 22 and each coupling part 50 are integrally formed, and the pair of piezoelectric actuators 40 are coupled to each other by a highly-rigid structure composed of the rib 22 and the coupling parts 50.

In Embodiments 1 and 2 described above, each coupling part 50 has a configuration in which the base layer 220 (Si substrate) is overlaid on the same device layer 210 (Si substrate) as in the movable part 21, and each coupling part 50 is formed so as to have a larger thickness than the movable part 21. However, the configuration of each coupling part 50 is not limited to the above configuration as long as the coupling part 50 has higher rigidity than the movable part 21. For example, each coupling part 50 may be composed of a material having higher rigidity than the movable part 21, and may have a thickness equal to that of the movable part 21. In addition, each coupling part 50 may be composed of a material having lower rigidity than the movable part 21, and may be formed so as to have a larger thickness than the movable part 21, thereby resulting in having higher rigidity than the movable part 21. Moreover, although each coupling part 50 has a two-layer structure with the device layer 210 and the base layer 220, the number of layers of the coupling part 50 is not limited thereto.

Moreover, the coupling part 50 may be reinforced by covering the periphery of the coupling part 50 with a metal material, whereby the rigidity of the coupling part 50 may be made higher than that of the movable part 21. FIG. 10B is a cross-sectional view schematically showing a configuration in this case. In FIG. 10B, each coupling part 50 is composed of the device layer 210 and a metal material 230, and the device layer 210 corresponding to the coupling part 50 is covered with the metal material 230. In the case of using the metal material 230 as described above, the rigidity of the coupling part 50 can be easily increased.

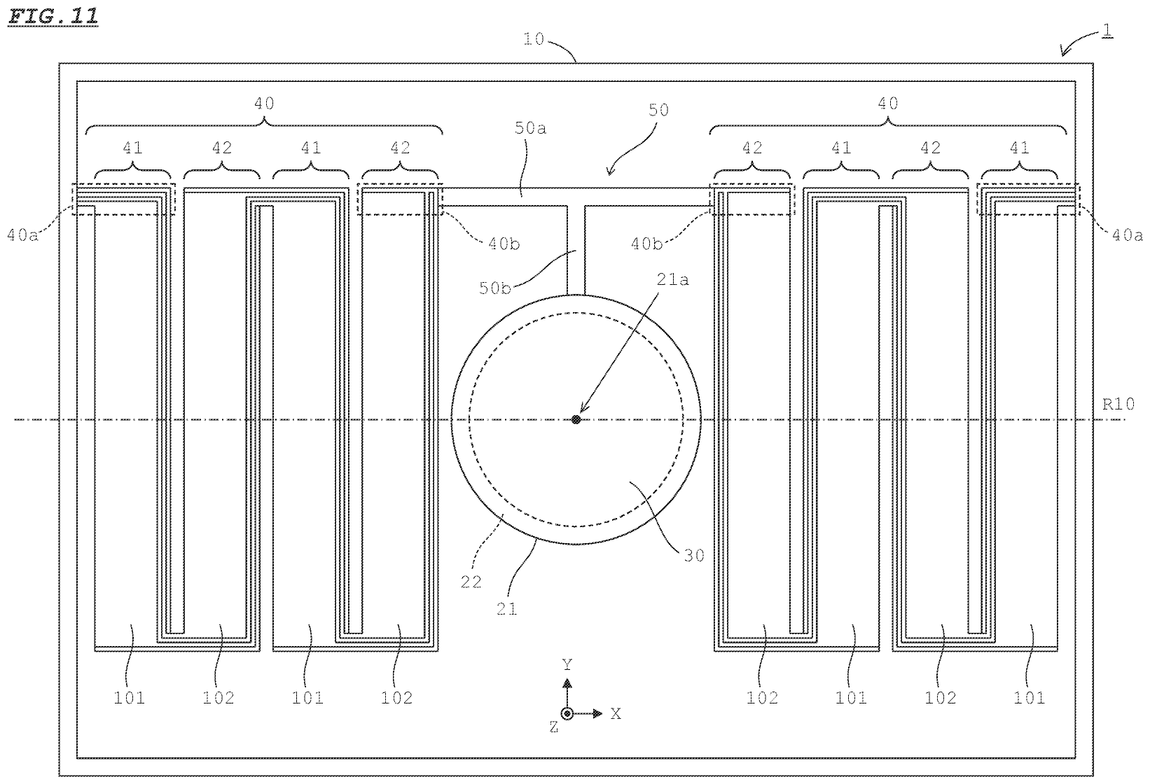

In Embodiments 1 and 2 described above, as shown in FIG. 11, the pair of piezoelectric actuators 40 may be disposed and configured so as to be line-symmetrical with respect to the Y-Z plane passing through the center 21a of the movable part 21. In this case, the pair of piezoelectric actuators 40 are connected to the movable part 21 and the rib 22 by one coupling part 50. In this case, the shape of the coupling part 50 is a T-shape that is line-symmetrical with respect to the Y-Z plane passing through the center 21a in a plan view. The coupling part 50 includes a straight portion 50a extending in the X-axis direction and a straight portion 50b extending in the Y-axis direction. The straight portion 50a connects the end portion 40b of the piezoelectric actuator 40 on the X-axis positive side and the end portion 40b of the piezoelectric actuator 40 on the X-axis negative side. The straight portion 50b connects the center in the X-axis direction of the straight portion 50a to the movable part 21 and the rib 22.

In the configuration shown in FIG. 11, the pair of piezoelectric actuators 40 are driven so as to cause rotational vibrations in the same direction as each other. Specifically, voltages having the same phase are applied to the upper electrodes 101 of the two piezoelectric actuators 40, and voltages each having a phase opposite to that of the voltages applied to the upper electrodes 101 are applied to the upper electrodes 102 of the two piezoelectric actuators 40. Accordingly, the straight portion 50a of the coupling part 50 rotates about the rotation axis R10, and the movable part 21 and the mirror 30 repeatedly rotationally vibrate.

In Embodiments 1 and 2 described above, each coupling part 50 is formed so as to have higher rigidity than the movable part 21. On the other hand, the inventor examined whether or not the driving characteristics of the movable part 21 was able to be enhanced by adjusting each coupling part 50 as in Model 2 described above, in the case where each coupling part 50 did not have higher rigidity than the movable part 21.

Hereinafter, a modification in this examination will be described.

The configuration of this modification is the same as in Embodiment 2 shown in FIG. 4 and FIG. 6C in a plan view. Each coupling part 50 of this modification is connected to the movable part 21 so as to be substantially included in a range between the straight line L1 connecting the connection position between the coupling part 50 and the piezoelectric actuator 40 (end portion 40b) and the center 21a of the movable part 21, and the rotation axis R10 of the movable part 21 by the piezoelectric actuator 40. In addition, the lamination structure of each coupling part 50 of this modification is configured so as to be the same as in each coupling part 51 of the comparative example shown in FIG. 5C. That is, each coupling part 50 is formed so as to have a thickness equal to that of the portion of the movable part 21 in a range other than the rib 22 of the comparative example. Moreover, the ribs 22 and 23 are disposed on the surface on the Z-axis negative side of the movable part 21 of this modification as in Embodiments 1 and 2 shown in FIGS. 6A to 6C. The lamination structure of the movable part 21 and the ribs 22 and 23 of this modification is the same as in Embodiments 1 and 2 shown in FIG. 6B.

For the driving characteristics of Model 3 corresponding to the configuration of the modification configured as described above, the inventor performed simulation by a finite element method as in the above simulation for the driving characteristics. Each dimension of Model 3 is the same as that of Model 2, except for the thickness of each coupling part 50. In addition, the thickness of each coupling part 50 of Model 3 is the same as that of the comparative example.

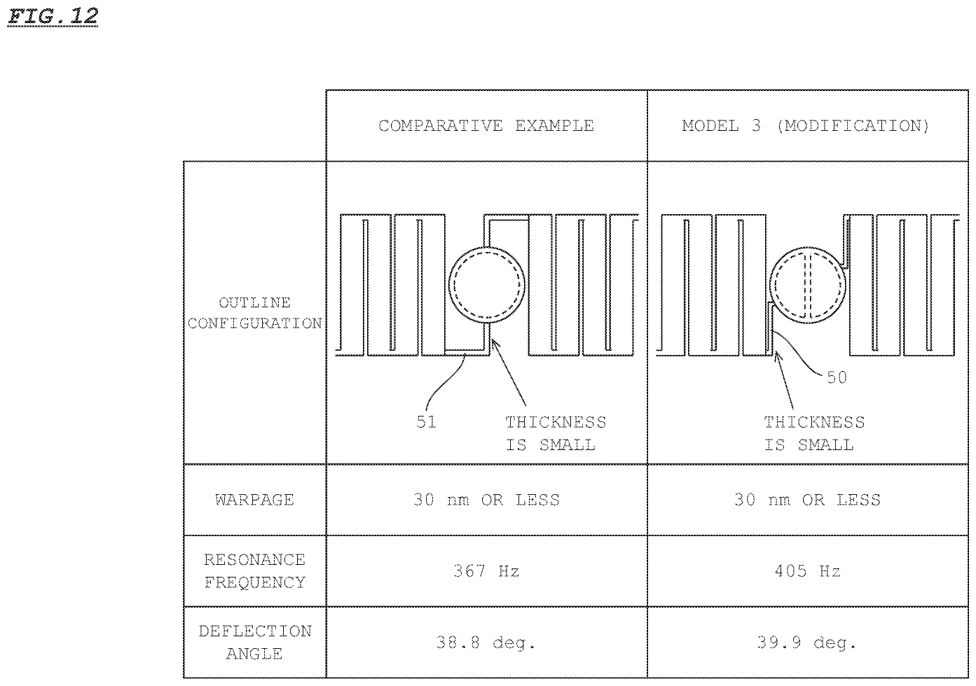

FIG. 12 is a table showing the results of this simulation. For convenience, FIG. 12 shows the simulation results of the comparative example in FIG. 7.

The value of the warpage of Model 3 was 30 nm or less. Therefore, it is confirmed that by disposing the ribs on the movable part 21 as in the comparative example and Models 1 and 2 in FIG. 7, warpage is suppressed.

The value of the resonance frequency of Model 3 was 405 Hz. In Model 3, the resonance frequency was slightly lower than those in Models 1 and 2 in FIG. 7, but a resonance frequency higher than that in the comparative example was obtained. From this, it is confirmed that even when the thickness of each coupling part 50 is decreased as in the comparative example, a higher resonance frequency is obtained by reducing the moment of inertia of the coupling part 50.

The value of the deflection angle of Model 3 was 39.9°. In Model 3, the deflection angle was slightly smaller than those in Models 1 and 2 in FIG. 7, but a deflection angle larger than that in the comparative example was obtained. From this, it is confirmed that even when the thickness of each coupling part 50 is decreased as in the comparative example, a larger deflection angle is obtained by reducing the moment of inertia of the coupling part 50 with respect to the rotation axis R10.

As described above, according to this modification, since each coupling part 50 is located in a range close to the rotation axis R10, the moment of inertia of the coupling part 50 with respect to the rotation axis R10 can be reduced. Therefore, while the warpage of the movable part 21 is suppressed by the rib 22, the resonance frequency of the element part (piezoelectric actuators 40, the coupling parts 50, and the movable part 21) can be increased as compared to the comparative example, so that a decrease in the driving characteristics of the mirror 30 can be suppressed.

In Embodiments 1 and 2 described above, one piezoelectric actuator 40 includes two vibration parts 41 and two vibration parts 42, but the number of vibration parts included in the piezoelectric actuator 40 is not limited thereto.

In Embodiments 1 and 2 described above, the mirror 30 is composed of a dielectric multilayer film, a metal film, or the like, but may be an optical reflection film other than a dielectric multilayer film and a metal film.

In addition to the above, various modifications can be made as appropriate to the embodiments of the present invention, without departing from the scope of the technological idea defined by the claims.

What is claimed is:

1. A piezoelectric driving element comprising:
a support;
a plate-shaped movable part on which a rib is disposed;
a pair of meander-type piezoelectric actuators each supported at one end thereof by the support; and
a coupling part coupling another end of each of the pair of piezoelectric actuators and the movable part and having higher rigidity than the movable part.

2. The piezoelectric driving element according to claim 1, wherein the coupling part has a larger thickness than the movable part.

3. The piezoelectric driving element according to claim 1, wherein an end portion of the coupling part extends to the rib and is connected to the rib.

4. The piezoelectric driving element according to claim 1, wherein the coupling part is connected to the movable part so as to be substantially included in a range between a straight line connecting a connection position between the coupling part and the piezoelectric actuator and a center of the movable part, and a rotation axis of the movable part by the piezoelectric actuator.

5. The piezoelectric driving element according to claim 1, wherein
the rib and the coupling part are composed of the same material, and
the coupling part has a thickness equal to a sum of thicknesses of the movable part and the rib.

6. The piezoelectric driving element according to claim 1, wherein the piezoelectric driving element is an element formed by processing a SOI substrate.

7. The piezoelectric driving element according to claim 1, wherein the coupling part is connected to the movable part at positions symmetrical with respect to a center of the movable part.

8. The piezoelectric driving element according to claim 1, wherein a mirror is disposed on the movable part.

9. A piezoelectric driving element comprising:
a support;
a plate-shaped movable part on which a rib is disposed;
a pair of meander-type piezoelectric actuators each supported at one end thereof by the support; and
a coupling part coupling another end of each of the pair of piezoelectric actuators and the movable part, wherein
the coupling part is connected to the movable part so as to be substantially included in a range between a straight line connecting a connection position between the coupling part and the piezoelectric actuator and a center of the movable part, and a rotation axis of the movable part by the piezoelectric actuator.

10. The piezoelectric driving element according to claim 9, wherein the coupling part is connected to the movable part at positions symmetrical with respect to a center of the movable part.

11. The piezoelectric driving element according to claim 9, wherein the piezoelectric driving element is an element formed by processing a SOI substrate.

12. The piezoelectric driving element according to claim 9, wherein a mirror is disposed on the movable part.
